(19) United States
(12) Patent Application Publication
(10) Pub. No.: US 2013/0168811 A1
(43) Pub. Date: Jul. 4, 2013

(54) CAPACITOR HAVING MULTI-LAYERED ELECTRODES

(71) Applicants: TZUNG-HAN LEE, TAIPEI CITY (TW); CHUNG-LIN HUANG, TAOYUAN COUNTY (TW); RON-FU CHU, TAIPEI CITY (TW)

(72) Inventors: TZUNG-HAN LEE, TAIPEI CITY (TW); CHUNG-LIN HUANG, TAOYUAN COUNTY (TW); RON-FU CHU, TAIPEI CITY (TW)

(73) Assignee: INOTERA MEMORIES, INC., TAOYUAN COUNTY (TW)

(21) Appl. No.: 13/417,438

(22) Filed: Mar. 12, 2012

(30) Foreign Application Priority Data
Jan. 4, 2012 (TW) 101100355

(51) Int. Cl. H01L 29/92

(52) U.S. Cl. 257/532; 257/E29.342

(57) ABSTRACT

The instant disclosure relates to a capacitor having multi-layered electrodes. The capacitor includes a dielectric layer having a first surface and a second surface oppositely arranged, a first electrode formed on the first surface, and a second electrode formed on the second surface. At least one of the first and second electrodes having a low band gap material layer formed on the dielectric layer and a conducting layer formed on the low band gap material layer. The band gap of the low band gap material layer is lower than the band gap of the conducting layer.

### BACKGROUND OF THE INVENTION

1. Field of the Invention

The instant disclosure relates to a semiconductor; more particularly, to a semiconductor utilizing low band gap material.

2. Descriptions of Related Art

For VLSI (very-large-scale integration), the memory design has become a main focus in addition to CMOS (complementary metal-oxide-semiconductor). The memory is classified as either volatile or non-volatile. Modern forms of RAM (random access memory) such as DRAM (dynamic random access memory) and SRAM (static random access memory) are volatile memories. When the power is cut off, the stored information in the volatile memory is lost. On the other hand, for non-volatile memory, the stored data will retain even when the power supply is cut off. DRAM and SRAM are commonly used in personal computers, while non-volatile memory is used mainly for mobile electronic devices.

Most forms of DRAM today require only one transistor and a capacitor. A DRAM cell may be constructed with deep trench capacitor. The capacitor is fabricated inside a deep trench formed on a silicon substrate. Such technology enables the designer to reduce the physical size of the memory and also reduce power consumption. The operation speed of the memory cell can also be increased. Moreover, for DRAM, the goal of increasing the data retention time is one of the major aspirations for the designers.

### SUMMARY OF THE INVENTION

The instant disclosure provides a capacitor capable of increasing the data retention time and structural durability of a memory cell.

The capacitor comprises a dielectric layer having opposite first and second surfaces, a first electrode formed on the first surface, and a second electrode formed on the second surface. At least one of the first and second electrodes having a low band gap material layer formed on the dielectric layer and a conducting layer formed on the low band gap material layer. The band gap of the low band gap material layer is lower than the band gap of the conducting layer.

The capacitor of the instant disclosure utilizes electrodes each having stacked layers of different band gaps to create a quantum well at the heterojunction. The memory cell thus can have better trapping ability of the electrons and electron holes enabling longer data retention time.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a schematic view of a capacitor for a first embodiment of the instant disclosure.

FIG. 2 shows an energy band diagram for the capacitor of the instant disclosure.

FIG. 3 shows a schematic view of a capacitor for a second embodiment of the instant disclosure.

FIG. 4 shows a circuit diagram of a memory cell utilizing the capacitor of the instant disclosure.

### DETAILED DESCRIPTION OF THE EMBODIMENTS

The instant disclosure provides a pair of electrodes for a capacitor of a DRAM, where each electrode is constructed with a lower band gap material layer and a conducting layer. A quantum well is created at the heterojunction between the low band gap material layer and the conducting layer. The capture of electrons and holes by the quantum well enables the memory cell to increase the data retention time. The capacitor of the instant disclosure includes a dielectric layer, a first electrode (also referred to as the top cell plate), and a second electrode (also referred to as the bottom cell plate). The first and second electrodes each have one low band gap material layer and one conducting layer. In other words, the capacitor of the instant disclosure has multi-layered electrode structures (i.e., the first and second electrodes). The creation of the quantum well by the low band gap material layer and the conducting layer in association with the first and second electrodes is capable of upgrading the operational characteristics of the memory cell.

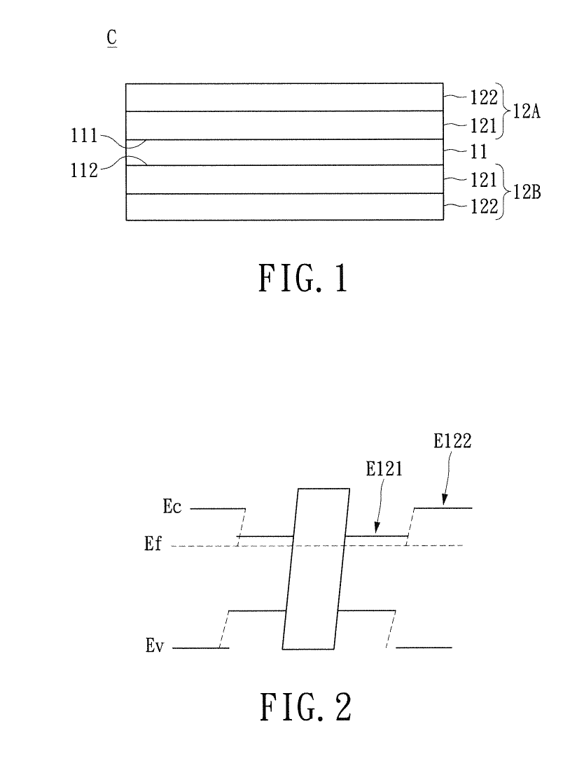

Please refer to FIG. 1, which shows a capacitor C for a first embodiment of the instant disclosure. The capacitor C includes a dielectric layer 11, a first electrode 12A, and a second electrode 12B. The dielectric layer 11 has two opposite surfaces, namely a first surface 111 and a second surface 112. The first and second electrodes 12A and 12B are formed on the first and second surfaces 111 and 112, respectively. The first and second electrodes 12A and 12B each has a low band gap material layer 121 and a conducting layer 122, where the low band gap material layer 121 is disposed on the dielectric layer 11. Because the low band gap material layer 121 has a lower band gap than the conducting layer 122, a quantum well can be created at the heterojunction between the low band gap material layer 121 and the conducting layer 122.

More specifically, the conducting layer 122 is preferably a semiconductor or a conductor, such as doped silicon. The low band gap material layer 121 preferably is a semiconductor material having a lower band gap than the conducting layer 122, such as silicon germanium, silicon nitride, aluminum nitride, or gallium nitride. The low band gap material layer 121 may be grown on the dielectric layer 11 in an epitaxial manner. The low band gap material layer 121 preferably has a band gap less than 1.1 eV. This value is lower than the band gap of the silicon-based conducting layer 122 of 1.12 eV. For example, the low band gap material layer 121 may be silicon germanium (Si₁₋ₓGeₓ). When x<0.85, the band gap is calculated by the following formula: 1.12−0.41x+0.008x² (eV). When x>0.85, the band gap is calculated by the following formula: 1.86−1.2x (eV). The low band gap material layer 121 can reduce the Schottky barrier that would be formed from direct contact between the dielectric layer 11 and the conducting layer 122. On the other hand, the quantum well is created at the heterojunction between the low band gap material layer 121 and the conducting layer 122. Please refer to FIG. 2, which shows an energy band diagram for the capacitor C. The energy bands of the low band gap material layer 121 and the conducting layer 122 are designated by the labels E121 and E122, respectively. The symbols Ec, Ef, and Ev denote the conduction band energy level, Fermi energy level, and valence band energy level, respectively. Furthermore, the silicon conducting layer 122 can be used to fill any undesired cracks/gaps on the silicon germanium-based low band gap material layer 121, to reinforce overall structural rigidity of the capacitor C.

Alternatively, the conducting layer 122 can be titanium nitride (TiN), which is a good conductor of electricity. The band gap of the titanium nitride is approximately 3.35 eV. The conducting layer 122 can be disposed on the low band gap material layer 121 by means of CVD (chemical vapor deposition), ALD (atomic layer deposition), MOCVD (metal-organic CVD), PVD (physical vapor deposition), or JVD (jet vapor deposition). Since the conducting layer 122 of titanium nitride has less electrical resistivity, the capacitor C can have better quality. Please note, the respective conducting layers 122 for the first and second electrodes 12A and 12B can be made using different materials. For example, the conducting layer 122 of the first electrode 12A can be silicon germanium, while the conducting layer 122 of the second electrode 12B can be titanium nitride.

For another variant of the instant embodiment, the low band gap material layer 121 can be made of gallium arsenide (GaAs) having a band gap of 1.424 eV. The conducting layer 122 can be made with aluminum gallium arsenide (AlₓGa₁₋ₓAs). When x<0.45, the band gap is calculated by a formula, which is: 1.424+1.247x (eV). When x>0.45, the band gap is calculated using the following formula instead: 1.9+0.125x+0.143x² (eV). The band gap difference that exists in each individual multi-layered electrode structure enables the capacitor C to trap the electrons or holes for enhancing the properties of the memory.

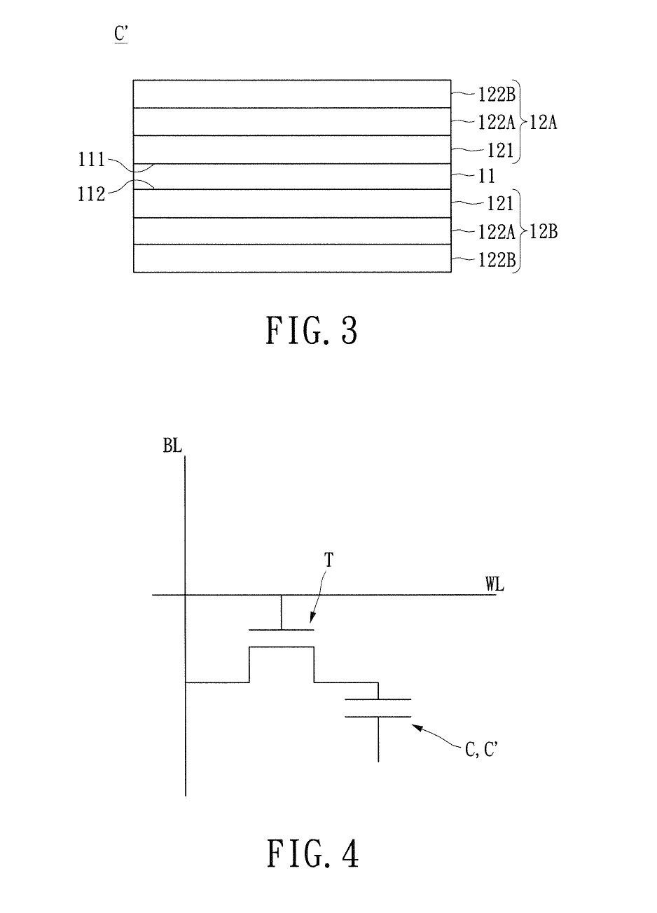

Please refer to FIG. 3, which shows a capacitor C′ for a second embodiment of the instant disclosure. The capacitor C′ comprises the dielectric layer 11, the first electrode 12A, and the second electrode 12B. The dielectric layer 11 having the first and second surfaces 111 and 112 oppositely arranged. The first and second electrodes 12A and 12B are formed on the first and second surfaces 111 and 112, respectively. For the instant embodiment, the first and second electrodes 12A and 12B each has one low band gap material layer 121, a first sub-conducting layer 122A, and a second sub-conducting layer 122B, where the low band gap material layer 121 is disposed on the dielectric layer 11. In other words, the conducting layer 122 of the first embodiment may include the first and second sub-conducting layers 122A and 122B. The band gap of the low band gap material 121 is less than the band gap of the first sub-conducting layer 122A. Thus, the quantum well can be formed at the heterogeneous junction between the low band gap material 121 and the first sub-conducting layer 122A.

For the instant embodiment, the low band gap material layer 121 is preferably made of a semiconductor material having a lower band gap in comparing to the first and second sub-conducting layers 122A and 122B, such as silicon germanium, silicon nitride, aluminum nitride, or gallium nitride. For example, the low band gap material layer 121 is grown epitaxially on the dielectric layer 11. The low band gap material layer 121 preferably has a band gap less than 1.1 eV. For example, the low band gap material layer 121 may be silicon germanium (Si₁₋ₓGeₓ). When x<0.85, the band gap is calculated by the following formula: 1.12−0.41x+0.008x² (eV). When x>0.85, the band gap is calculated by the following formula: 1.86−1.2x (eV).

Meanwhile, the first sub-conducting layer 122A is preferably a semiconductor or a conductor, such as doped silicon. The band gap of the silicon-based first sub-conducting layer 122A is 1.12 eV, and this silicon-based first sub-conducting layer 122A can be grown epitaxially on the low band gap material layer 121. The second sub-conducting layer 122B can be titanium nitride (TiN), which is a good conductor of electricity. The band gap of the titanium nitride is approximately 3.35 eV. The second sub-conducting layer 122B can be disposed on the first sub-conducting layer 122A by means of CVD (chemical vapor deposition), ALD (atomic layer deposition), MOCVD (metal-organic CVD), PVD (physical vapor deposition), or JVD (jet vapor deposition). The selected material and corresponding material properties of the first and second sub-conducting layers 122A and 122B are capable of enhancing the structural rigidity and operating properties of the capacitor C′.

Alternatively, the first sub-conducting layer 122A for the first electrode 12A and the first sub-conducting layer 122A for the second electrode 12B may be made with different materials, with the same condition applicable to the second sub-conducting layer 122B. For example, the first and second sub-conducting layers 122A and 122B of the first electrode 12A can be made of doped silicon and titanium nitride, respectively. Whereas the first and second sub-conducting layers 122A and 122B of the second electrode 12B can be made of titanium nitride and doped silicon, respectively.

Furthermore, the two electrodes for the capacitor may not be structurally symmetrical. For example, the first electrode 12A may be a double-layered structure having the low band gap layer 121 and the conducting layer 122 (as described in the first embodiment). Whereas the second electrode 12B is a tri-layer structure having the low band gap layer 121, the first sub-conducting layer 122A, and the second sub-conducting layer 122B (as described in the second embodiment). Regardless of the type of structure, any multi-layered structure having the low band gap layer 121 and at least one conducting layer 122 is permissible.

Please refer to FIG. 4, which shows a circuit diagram for a memory cell operated by the capacitor C, C′ of the instant disclosure. Specifically, the information is stored in the capacitor C, C′ in form of electrical charge. A transistor T is used to control the transfer of charge in and out of the capacitor C, C′. Access to the memory cell is enabled by a word line WL which supplies voltage to switch the transistor T on or off. A bit line BL is utilized through which information is written/read to/from the memory cell. In other words, the information can be stored (i.e., write) to or extracted (i.e., read) from the memory cell through the bit line BL. For the instant disclosure, since the electrodes of the capacitor has improved electron or electron hole trapping capability, the data retention time of the memory cell can be increased.

The instant disclosure has the following advantages. First, the formation of the quantum well at the heterogeneous junction improves the electron or electron hole trapping ability of the capacitor. Secondly, the electrodes are structurally rigid in providing better durability for the memory cell. Thirdly, the electrodes have low electrical resistivity which enhances the operational characteristics of the capacitor.

The descriptions illustrated supra set forth simply the preferred embodiments of the present invention; however, the characteristics of the instant disclosure are by no means restricted thereto. All changes, alternations, or modifications conveniently considered by those skilled in the art are deemed to be encompassed within the scope of the present invention delineated by the following claims.

What is claimed is:

1. A capacitor having multi-layered electrodes, comprising:
a dielectric layer having a first surface and a second surface, with the first and second surfaces being opposite of each other;
a first electrode formed on the first surface; and
a second electrode formed on the second surface,
wherein at least one of the first and second electrodes having a low band gap material layer formed on the dielectric layer and a conducting layer formed on the low band gap material layer, wherein the band gap of the low band gap material layer is lower than the band gap of the conducting layer.

2. The capacitor having multi-layered electrodes of claim 1, wherein the first and second electrodes each having one low band gap material layer and one conducting layer.

3. The capacitor having multi-layered electrodes of claim 2, wherein the band gap of the low band gap material layer is less than 1.1 eV.

4. The capacitor having multi-layered electrodes of claim 2, wherein the low band gap material layer is made of silicon germanium and the conducting layer is made of doped silicon.

5. The capacitor having multi-layered electrodes of claim 2, wherein the low band gap material layer is made of silicon germanium and the conducting layer is made of titanium nitride.

6. The capacitor having multi-layered electrodes of claim 2, wherein the low band gap material layer is made of gallium arsenide and the conducting layer is made of aluminum gallium arsenide.

7. The capacitor having multi-layered electrodes of claim 1, wherein the conducting layer includes a first sub-conducting layer disposed on the low band gap material layer and a second sub-conducting layer disposed on the first sub-conducting layer.

8. The capacitor having multi-layered electrodes of claim 7, wherein the first and second electrodes each having one low band gap material layer, one first sub-conducting layer, and one second sub-conducting layer.

9. The capacitor having multi-layered electrodes of claim 8, wherein the band gap of the low band gap material layer is less than 1.1 eV.

10. The capacitor having multi-layered electrodes of claim 8, wherein the low band gap material layer is made of silicon germanium, and wherein the first sub-conducting layer is made of doped silicon and the second sub-conducting layer is made of titanium nitride or vice versa.
